(19) United States
(12) Patent Application Publication
(10) Pub. No.: US 2023/0209917 A1
(43) Pub. Date: Jun. 29, 2023

(54) BOTTOM EMISSION TYPE ELECTROLUMINESCENCE DISPLAY

(71) Applicant: LG DISPLAY CO., LTD., SEOUL (KR)

(72) Inventor: Seonryeol PARK, Paju-si (KR)

(73) Assignee: LG DISPLAY CO., LTD., SEOUL (KR)

(21) Appl. No.: 17/942,202

(22) Filed: Sep. 12, 2022

(30) Foreign Application Priority Data
Dec. 29, 2021 (KR) 10-2021-0191103

(51) Int. Cl. H01L 27/32; H01L 51/52

(52) U.S. Cl. CPC H01L 27/3258; H01L 51/5218; H01L 51/5234; H01L 27/3213

(57) ABSTRACT

An electroluminescence display includes a pixel area disposed on a substrate, the pixel area including an emission area and a non-emission area, a driving element disposed in the non-emission area, a passivation layer on the driving element; a color filter disposed in the pixel area on the passivation layer, a planarization layer on the color filter, a first contact hole penetrating the passivation layer and exposing the driving element, a second contact hole penetrating the planarization layer and exposing the first contact hole, and a light emitting element disposed at the emission area on the planarization layer, and the first contact hole is disposed in the second contact hole as being biased toward a first side

### CROSS-REFERENCE TO RELATED APPLICATION

This application claims the benefit of the Korean Patent Application No. 10-2021-0191103 filed on Dec. 29, 2021, which is hereby incorporated by reference in its entirety.

### BACKGROUND

### Field of the Disclosure

The present disclosure relates to a bottom emission type electroluminescence display. Especially, the present disclosure relates to a bottom emission type electroluminescence display having a structure for solving a disconnection problem at a contact hole connecting a light emitting element and a driving element in an ultra-high resolution display.

### Description of the Background

Recently, various type of display such as the cathode ray tubes (CRTs), the liquid crystal displays (LCDs), the plasma display panels (PDPs) and the electroluminescent displays have been developed. These various types of display are used to display image data of various products such as computer, mobile phones, bank deposit and withdrawal devices (ATMs), and vehicle navigation systems according to their unique characteristics and purposes.

In particular, the electroluminescent display which is a self-luminous display, has an excellent optical performance such as a viewing angle and color realization degree, so that its application field is gradually widening and is receiving attention as an image display device. Due to these advantages, it is attracting attention as the most suitable display for implementing 4K or 8K ultra-high resolution display. As the resolution is increased, the size of the pixel becomes smaller and the size of the emission area occupied in the pixel also becomes smaller.

In the case of the bottom emission type, ultra-high resolution may be implemented by minimizing the area ratio of the driving element in the pixel area and maximizing the area ratio occupied by the light emitting element in the pixel area. In addition, the area of the contact hole for connecting the light emitting element and the driving element may be as small as possible. When the area is too small, the connection in the contact hole may be defective.

In addition, as a color filter is disposed between the light emitting element and the driving element, a minimum distance between the color filter and the contact hole may be ensured. Due to various restrictions, the possibility of a connection failure in the contact hole is very high in implementing the ultra-high resolution. Accordingly, it is necessary to develop a new structure of a bottom emission type display capable of ensuring the connectivity between a driving element and the light emitting element in a contact hole while implementing ultra-high resolution.

### SUMMARY

For solving the problems described above, the present disclosure is to provide an electroluminescence display having an ultra-high resolution. Another purpose of the present disclosure is to provide an electroluminescence display having ultra-high resolution by minimizing an area ratio occupied by a contact hole connection between an anode electrode and a driving element. Still another purpose of the present disclosure is to provide an electroluminescence display which does not cause problems such as contact failure at an anode electrode in implementing ultra-high resolution.

In order to accomplish the above mentioned according to the present disclosure, an electroluminescence display includes a pixel area disposed on a substrate, the pixel area including an emission area and a non-emission area; a driving element disposed in the non-emission area; a passivation layer on the driving element; a color filter disposed in the pixel area on the passivation layer; a planarization layer on the color filter; a first contact hole penetrating the passivation layer and exposing the driving element; a second contact hole penetrating the planarization layer and exposing the first contact hole; and a light emitting element disposed at the emission area on the planarization layer. The first contact hole is disposed in the second contact hole as being biased toward a first side.

In one aspect of the present disclosure, the color filter is apart from the second contact hole with a predetermined distance.

In one aspect of the present disclosure, the second contact hole includes: a first side having a first inclined angle; and a second side having a second inclined angle smaller than the first inclined angle. The first side is disposed at the first side of the second contact hole. The first side is closest apart from the first contact hole the second side is disposed at a second side of the second contact hole, the second side is furthest apart from the first contact hole.

In one aspect of the present disclosure, the first inclined angle is any one of 60 degree to 80 degree. The second inclined angle is any one of 30 degree to 50 degree.

In one aspect of the present disclosure, the first contact hole includes a first side, a second side, a third side and a fourth side. The second contact hole includes a fifth side parallel to and apart from the first side with a first distance, a sixth side parallel to and apart from the second side with a second distance, a seventh side parallel to and apart from the third side with a third distance, and a eighth side parallel to and apart from the fourth side with a fourth distance. The first distance and the second distance and the third distance are same. the fourth distance is longer than the first distance.

In one aspect of the present disclosure, the second contact hole includes: a first inclined sidewall disposed at the fifth side; and a second inclined sidewall disposed at the eighth side. The second inclined sidewall has a second inclined angle smaller than a first inclined angle of the first inclined sidewall.

In one aspect of the present disclosure, the first inclined angle is any one of 60 degree to 80 degree. The second inclined angle is any one of 30 degree to 50 degree.

In one aspect of the present disclosure, the light emitting element includes: a first electrode connected to the driving element; an emission layer on the first electrode; and a second electrode on the emission layer.

In one aspect of the present disclosure, the first electrode includes a transparent conductive material having any one of indium-zinc-oxide and indium-tin-oxide.

In one aspect of the present disclosure, the second electrode includes a reflective metal material having any one of aluminum, silver, molybdenum, gold, magnesium, calcium and barium.

In one aspect of the present disclosure, the driving element includes: a semiconductor layer on the substrate; a gate insulating layer on the semiconductor layer; a gate electrode on the gate insulating layer, the gate electrode overlapping with a middle portion of the semiconductor layer; a source electrode on the gate insulating layer, the source electrode contacting one side of the semiconductor layer; and a drain electrode on the gate insulating layer, the drain electrode contacting another side of the semiconductor layer.

The electroluminescent display according to the present disclosure may minimize the area ratio of the contact hole connecting the anode electrode and the driving element to implement the ultra-high resolution electroluminescence display. Accordingly, the aperture ratio, which is the ratio of the emission area to the pixel area, may be ensured as much as possible in the ultra-high resolution. In addition, in the electroluminescence display implementing ultra-high resolution, only one side of the contact hole connecting the anode electrode and the driving element is widened, thereby ensuring the connectivity between the anode electrode and the driving element. Accordingly, in implementing the ultra-high resolution, a problem such as contact failure in the anode electrode may not occur.

The present application provides an electroluminescence display having a high aperture ratio without causing defects as implementing ultra-high resolution and with being able to ensure physical and electrical connectivity in a contact hole connecting a light emitting element and a driving element.

### BRIEF DESCRIPTION OF THE DRAWINGS

The accompanying drawings, which are included to provide a further understanding of the disclosure and are incorporated in and constitute a part of this application, illustrate aspects of the disclosure and together with the description serve to explain the principle of the disclosure.

In the drawings:

FIG. 1 is a plane view illustrating a schematic structure of an electroluminescence display according to the present disclosure.

FIG. 2 is a circuit diagram illustrating a structure of one pixel according to the present disclosure.

FIG. 3 is a plan view illustrating a structure of the pixels disposed in the electroluminescence display according to the present disclosure.

FIG. 4 is a cross-sectional view along the cutting line I-I′ in FIG. 3, for illustrating the structure of the electroluminescence display according to the present disclosure.

FIG. 5 is an enlarged plane view illustrating a detailed structure of dotted circle part ‘V1’ in FIG. 3 according to the first aspect of the present disclosure.

FIG. 6 is a cross-sectional view along the cutting line II-IF in FIG. 5, for illustrating a structure of an electroluminescence display according to the first aspect of the present disclosure.

FIG. 7 is an enlarged plane view illustrating a detailed structure of dotted circle part ‘V1’ in FIG. 3 according to the second aspect of the present disclosure.

FIG. 8 is a cross-sectional view along the cutting line in FIG. 6, for illustrating a structure of an electroluminescence display according to the second aspect of the present disclosure.

### DETAILED DESCRIPTION

Advantages and features of the present disclosure, and implementation methods thereof will be clarified through following aspects described with reference to the accompanying drawings. The present disclosure may, however, be embodied in different forms and should not be construed as limited to the aspects set forth herein. Rather, these example aspects are provided so that this disclosure may be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings in order to describe various example aspects of the present disclosure, are merely given by way of example. Therefore, the present disclosure is not limited to the illustrated details. Like reference numerals refer to like elements throughout the specification unless otherwise specified. In the following description, where the detailed description of the relevant known function or configuration may unnecessarily obscure an important point of the present disclosure, a detailed description of such known function or configuration may be omitted.

Reference will now be made in detail to the exemplary aspects of the present disclosure, examples of which are illustrated in the accompanying drawings. Wherever possible, the same reference numbers will be used throughout the drawings to refer to the same or like parts. In the specification, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the specification should be understood as follows.

In the case that “comprise,” “have,” and “include” described in the present specification are used, another part may also be present unless “only” is used. The terms in a singular form may include plural forms unless noted to the contrary.

In construing an element, the element is construed as including an error range although there is no explicit description.

In describing a positional relationship, for example, when the positional order is described as “on,” “above,” “below,” and “next,” the case of no contact there-between may be included, unless “just” or “direct” is used. If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing the elements of the present disclosure, terms such as the first, the second, A, B, (a) and (b) may be used. These terms are only to distinguish the elements from other elements, and the terms are not limited in nature, order, sequence or number of the elements. When an element is described as being “linked”, “coupled” or “connected” to another element that element may be directly connected to or connected to that other element, but indirectly unless otherwise specified. It is to be understood that other elements may be “interposed” between each element that may be connected to or coupled to.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various aspects of the present disclosure may be partially or overall coupled to or combined with each other, and may be variously inter-operated with each other and driven technically as those skilled in the art can sufficiently understand. The aspects of the present disclosure may be carried out independently from each other, or may be carried out together in a co-dependent relationship.

Hereinafter, an example of a display apparatus according to the present disclosure will be described in detail with reference to the accompanying drawings. In designating reference numerals to elements of each drawing, the same components may have the same reference numerals as much as possible even though they are shown in different drawings.

Hereinafter, referring to attached figures, we will explain about the present disclosure, in detail. FIG. 1 is a diagram illustrating a schematic structure of an electroluminescence display according to the present disclosure. In FIG. 1, X-axis may be parallel to the extending direction of the scan line, Y-axis may be parallel to the extending direction of the data line, and Z-axis may represent the thickness direction of the display.

Referring to FIG. 1, the electroluminescence display comprises a substrate 110, a gate (or scan) driver 200, a data pad portion 300, a source driving IC (Integrated Circuit) 410, a flexible film 430, a circuit board 450, and a timing controller 500.

The substrate 110 may include an electrical insulating material or a flexible material. The substrate 110 may be made of a glass, a metal or a plastic, but it is not limited thereto. When the electroluminescence display is a flexible display, the substrate 110 may be made of the flexible material such as plastic. For example, the substrate 110 may include a transparent polyimide material.

The substrate 110 may include a display area AA and a non-display area NDA. The display area DA, which is an area for representing the video images, may be defined as the majority middle area of the substrate 110, but it is not limited thereto. In the display area AA, a plurality of scan lines (or gate lines), a plurality of data lines and a plurality of pixels may be formed or disposed. Each of pixels may include a plurality of sub pixels. Each of sub pixels includes the scan line and the data line, respectively.

The non-display area NDA, which is an area not representing the video images, may be defined at the circumference areas of the substrate 110 surrounding all or some of the display area AA. In the non-display area NDA, the gate driver 200 and the data pad portion 300 may be formed or disposed.

The gate driver 200 may supply the scan (or gate) signals to the scan lines according to the gate control signal received from the timing controller 500. The gate driver 200 may be formed at the non-display area NDA at any one outside of the display area AA on the substrate 110, as a GIP (Gate driver In Panel) type. GIP type means that the gate driver 200 is directly formed on the substrate 110.

The data pad portion 300 may supply the data signals to the data line according to the data control signal received from the timing controller 500. The data pad portion 300 may be made as a driver chip and mounted on the flexible film 430. Further, the flexible film 430 may be attached at the non-display area NDA at any one outside of the display area AA on the substrate 110, as a TAB (Tape Automated Bonding) type.

The source driving IC 410 may receive the digital video data and the source control signal from the timing controller 500. The source driving IC 410 may convert the digital video data into the analog data voltages according to the source control signal and then supply that to the data lines. When the source driving IC 410 is made as a chip type, it may be installed on the flexible film 430 as a COF (Chip On Film) or COP (Chip On Plastic) type.

The flexible film 430 may include a plurality of first link lines connecting the data pad portion 300 to the source driving IC 410, and a plurality of second link lines connecting the data pad portion 300 to the circuit board 450. The flexible film 430 may be attached on the data pad portion 300 using an anisotropic conducting film, so that the data pad portion 310 may be connected to the first link lines of the flexible film 430.

The circuit board 450 may be attached to the flexible film 430. The circuit board 450 may include a plurality of circuits implemented as the driving chips. For example, the circuit board 450 may be a printed circuit board or a flexible printed circuit board.

The timing controller 500 may receive the digital video data and the timing signal from an external system board through the line cables of the circuit board 450. The timing controller 500 may generate a gate control signal for controlling the operation timing of the gate driver 200 and a source control signal for controlling the source driving IC 410, based on the timing signal. The timing controller 500 may supply the gate control signal to the gate driver 200 and supply the source control signal to the source driving IC 410. Depending on the product types, the timing controller 500 may be formed as one chip with the source driving IC 410 and mounted on the substrate 110.

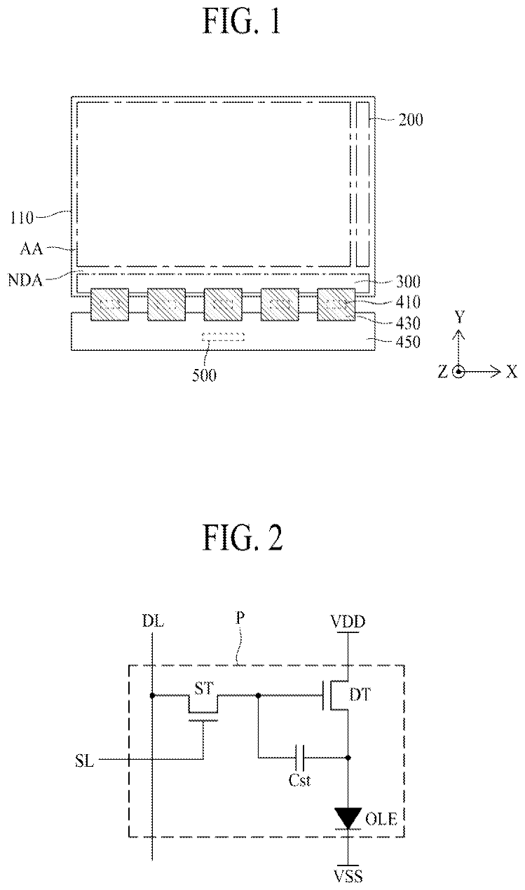

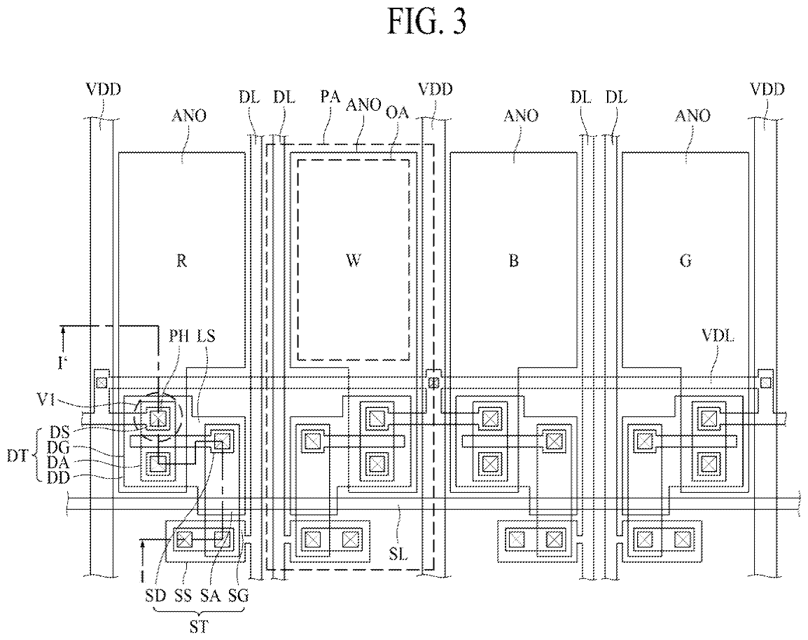

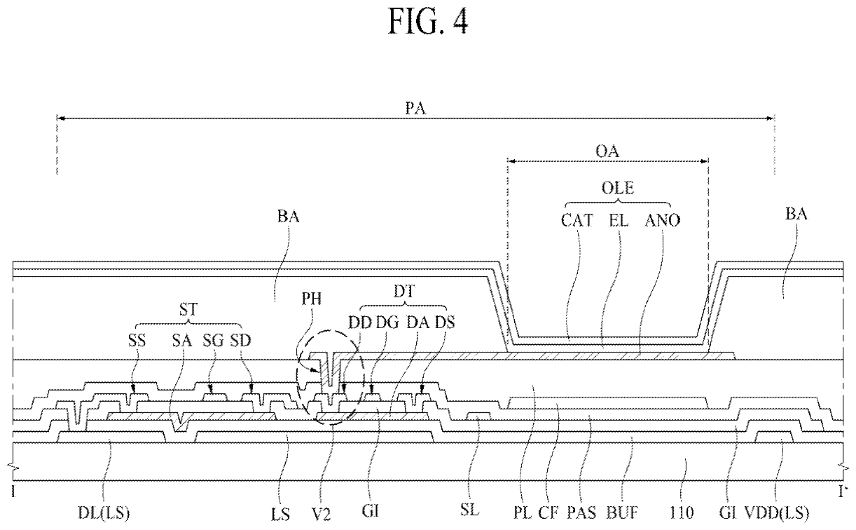

Referring to FIGS. 2 to 4, an electroluminescence display according to the present disclosure will be explained. FIG. 2 is a circuit diagram illustrating a structure of one pixel according to the present disclosure. FIG. 3 is a plan view illustrating a structure of the pixels according to the present disclosure. FIG. 4 is a cross-sectional view along the cutting line I-I′ in FIG. 3, for illustrating the structure of the electroluminescence display according to the present disclosure.

Referring to FIGS. 2 to 4, the electroluminescence display comprises a plurality of pixels P on a substrate 110. One pixel P may be allocated for each color unit. For example, there are a red pixel R representing red color, a green pixel G representing green color and a blue pixel B representing blue color. In addition, a white pixel W representing white color may be further included for enhancing the luminance. The area occupied by the pixel P may be defined as a pixel area PA. The pixel area PA may include an emission area OA and a non-emission area. The emission area OA is an area in which the light emitting diode OLE is disposed and provides light having a luminance corresponding to image information. The non-emission area is an area surrounding the emission area OA and is an area in which lines and driving elements are disposed.

One pixel P of the light emitting display may be defined by a scan line SL, a data line DL and a driving current line VDD. One pixel of the light emitting display may include a switching thin film transistor ST, a driving thin film transistor DT, a light emitting diode OLE and a storage capacitance Cst. The driving current line VDD may be supplied with a high-level voltage for driving the light emitting diode OLE.

For example, the switching thin film transistor ST may be disposed at the portion where the scan line SL and the data line DL is crossing. The switching thin film transistor ST may include a switching gate electrode SG, a switching source electrode SS and a switching drain electrode SD. The switching gate electrode SG may be connected to the scan line SL. The switching source electrode SS may be connected to the data line DL and the switching drain electrode SD may be connected to the driving thin film transistor DT. By supplying the data signal to the driving thin film transistor DT, the switching thin film transistor ST may play a role of selecting a pixel which would be driven.

The driving thin film transistor DT may play a role of driving the light emitting diode OLE of the selected pixel by the switching thin film transistor ST. The driving thin film transistor DT may include a driving gate electrode DG, a driving source electrode DS and a driving drain electrode DD. The driving gate electrode DG may be connected to the switching drain electrode SD of the switching thin film transistor ST. For example, the switching drain electrode SD may be connected to the driving gate electrode DG via a drain contact hole DH penetrating the gate insulating layer GI covering the driving gate electrode DG. The driving source electrode DS may be connected to the driving current line VSS, and the driving drain electrode DD may be connected to an anode electrode ANO of the light emitting diode OLE. A storage capacitance Cst may be disposed between the driving gate electrode DG of the driving thin film transistor DT and the anode electrode ANO of the light emitting diode OLE.

The driving thin film transistor DT may be disposed between the driving current line VDD and the light emitting diode OLE. The driving thin film transistor DT may control the amount of electric currents flowing to the light emitting diode OLE from the driving current line VDD according to the voltage level of the driving gate electrode DG connected to the switching drain electrode SD of the switching thin film transistor ST.

The light emitting diode OLE may include an anode electrode ANO, an emission layer EL and a cathode electrode CAT. The light emitting diode OLE may emit the light according to the amount of the electric current controlled by the driving thin film transistor DT. In other word, the light emitting diode OLE may be driven by the voltage differences between the low-level voltage and the high-level voltage controlled by driving thin film transistor DT.

Referring to FIG. 4, the cross-sectional structure of the electroluminescence display according to the first aspect of the present disclosure will be described. A light shield layer LS is formed on the substrate 110. The light shield layer LS may be used as the data line DL and driving current line VDD. In addition, the light shield layer LS may be further disposed as an island shape as overlapping with the semiconductor layers SA and DA and being separated from the data line DL and the driving current line VDD with a predetermined distance. The light shield layer LS not used for lines may block the external light from intruding into the semiconductor layers SA and DA for preventing the characteristics of the semiconductor layers SA and DA from being deteriorated. In particular, the light shield layer LS may overlap with the channel areas of the semiconductor layers SA and DA which overlap with the gate electrodes SG and DG. In addition, the light shield layer LS may further overlap with a portion of the source-drain electrodes SS, SD, DS and DD connecting to the semiconductor layers SA and DA.

A buffer layer BUF is deposited on the entire surface of the substrate 110 and on the light shield layer LS. The switching semiconductor layer SA and the driving semiconductor layer DA are formed on the buffer layer BUF. In particular, that the channel areas of the semiconductor layer SA and DA may overlap with the light shield layer LS.

The gate insulating layer GI is deposited on the surface of the substrate 110 having the semiconductor layers SA and DA. The switching gate electrode SG overlapping with the switching semiconductor layer SA and the driving gate electrode DG overlapping with driving semiconductor layer DA are formed on the gate insulating layer GI. In addition, the switching source electrode SS and the switching drain electrode SD are formed at both side of the switching gate electrode SG, respectively. The switching source electrode SS may contact one side of the switching semiconductor layer SA and be separated from the switching gate electrode SG. The switching drain electrode SD may contact another side of the switching semiconductor layer SA and be separated from the switching gate electrode SG. Similarly, the driving source electrode DS and the driving drain electrode DD are formed at both side of the driving gate electrode DG, respectively. The driving source electrode DS may contact one side of the driving semiconductor layer DA and be separated from the driving gate electrode DG. The driving drain electrode DD may contact another side of the driving semiconductor layer DA and be separated from the driving gate electrode DG.

The gate electrodes SG and DG and the source-drain electrodes SS, SD, DS and DD may be formed on the same layer, but they are separated each other. In addition, the switching source electrode SS may connect to the data line DL formed of a portion of the light shield layer LS via a contact hole penetrating the gate insulating layer GI and the buffer layer BUF. Similarly, the driving source electrode DS may connect to the driving current line VDD formed of another portion of the light shield layer LS via another contact hole penetrating the gate insulating layer GI and the buffer layer BUF. Accordingly, the switching thin film transistor ST and the driving thin film transistor DT are formed on the substrate 110.

The passivation layer PAS is deposited on the substrate 110 having the thin film transistors ST and DT. The passivation layer PAS may include at least one of silicon oxide and silicon nitride. The color filters CF may be formed on the passivation layer PAS. The color filter CF may be an element representing a color assigned to each pixel. For example, the color filter CF may have shape and size corresponding to the entire area of one pixel. For another example, the color filter CF may have a size slightly larger than that of the light emitting diode OLE to be formed later and may be disposed to overlap with the light emitting diode OLE.

The planarization layer PL is formed on the color filter CF. The planarization layer PL may be a thin layer for flattening the non-uniform (or uneven) surface of the substrate 110 on which the thin film transistors ST and DT are formed. In order to make the height difference uniform, the planarization layer PL may be formed of an organic material. The pixel contact hole PH may be formed at the passivation layer PAS and the planarization layer PL for exposing a portion of the driving drain electrode DD of the driving thin film transistor DT.

The anode electrode ANO is formed on the top surface of the planarization layer PL. The anode electrode ANO may contact the driving drain electrode DD of the driving thin film transistor DT via the pixel contact hole PH. The anode electrode ANO may have different configuration according to the light emitting type of the light emitting diode OLE. In the case of the bottom emission type that provides light in the direction of the substrate 110, the anode electrode ANO may be formed of a transparent conductive material. In the case of the top emission type that provides light in the opposite direction of the substrate 110, the anode electrode ANO may be formed of a metal material having excellent light reflectance.

In the case of a large area display such as a TV set, the cathode electrode CAT is formed as one layer over the large area, and it is needed to maintain a uniform low electric voltage over the large area of the cathode electrode CAT. Accordingly, in the case of a large-area display, the cathode electrode CAT may be formed of an opaque metal material. In the case of the bottom emission type, the anode electrode ANO may be made of a transparent conductive material. For example, the anode electrode ANO may include an oxide conductive material such as indium-zinc-oxide or indium-tin-oxide.

A bank BA is formed on the anode electrode ANO. The bank BA may cover the circumference areas of the anode electrode ANO, and expose most of middle portions of the anode electrode ANO. The exposed area of the anode electrode ANO by the bank BA may be defined as an emission area OA of the pixel.

The emission layer EL is deposited on the anode electrode ANO. The emission layer EL may be formed on the entire display area AA of the substrate 110 to cover the anode electrode ANO and the bank BA.

For another aspect, the emission layer EL may include any one of blue emission layer, green emission layer and red emission layer for providing color light allocated at the pixel. In this case, the emission layer EL may be deposed as being isolated within each emission area defined by the bank BA. In addition, the light emitting diode OLE may further include functional layers for enhancing the emission efficiency and/or the life time of the emission layer EL.

A cathode electrode CAT is deposited on the emission layer EL as being in surface-contact with the emission layer EL. The cathode electrode CAT is deposited as covering whole surface of the substrate 110 as being in connected with the emission layer EL disposed at all pixels. For the bottom emission type, the cathode electrode CAT may include a metal material having excellent light reflectance. For example, the cathode electrode CAT may include at least one of aluminum Al, silver Ag, molybdenum Mo, gold Au, magnesium Mg, calcium Ca and barium Ba or an alloy of any two of them.

Hereinafter, referring to figures, various aspects for the structure of the pixel contact hole PH where the drain electrode DD of the driving thin film transistor DT connects the anode electrode ANO will be described in detail.

<First Aspect>

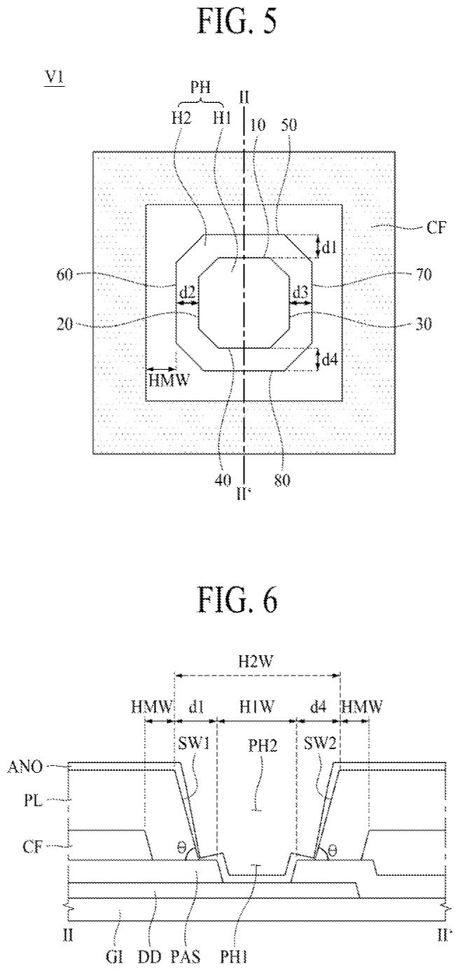

Hereinafter, referring to FIGS. 5 and 6, the first aspect of the present disclosure will be explained. FIG. 5 is an enlarged plane view illustrating a detailed structure of dotted circle part ‘V1’ in FIG. 3 according to the first aspect of the present disclosure. FIG. 6 is a cross-sectional view along the cutting line II-IF in FIG. 5, for illustrating a structure of an electroluminescence display according to the first aspect of the present disclosure.

In the following description, a plane view structure and a cross-sectional structure will be described together. The pixel contact hole PH is the contact hole for connecting the anode electrode ANO of the light emitting diode OLE to the driving drain electrode DD of the driving thin film transistor DT. The pixel contact hole PH is for exposing the driving drain electrode DD, and passes through the passivation layer PAS and the planarization layer PL covering the driving drain electrode DD. Therefore, the pixel contact hole PH may include a first contact hole H1 penetrating the passivation layer PAS and a second contact hole H2 penetrating the planarization layer PL. The first contact hole H1 may have any one shape of a circle, rectangle, hexagon or octagon. Here, in a plane view, a polygon having at least four sides will be used for explanation regardless of the shape.

Since the second contact hole H2 is formed later, the second contact hole H2 may have a larger size than the first contact hole H1. In addition, the first and second contact holes H1 and H2 may form a concentric shape in which the center point of the first contact hole H1 and the center point of the second contact hole H2 coincide in the cross-sectional view. In a plane view, the first contact hole H1 is included in the second contact hole H2, and four sides of the first contact hole H1 are spaced apart from each side of the second contact hole H2 by the same distance. For example, the first contact hole H1 may include a first side 10, a second side 20, a third side 30 and a fourth side 40. Similarly, the second contact hole H2 may include a fifth side 50, a sixth side 60, a seventh side 70, and an eighth side 80.

The distance between the first contact hole H1 and the second contact hole H2 may be set in consideration of a process margin and the like. For example, the second contact hole H2 may be formed as fully opening the first contact hole H1. The second contact hole H2 may have a size sufficient to expose a portion of the top surface of the passivation layer PAS disposed around the first contact hole H1. With this structure, the first side 10 may be spaced apart from the fifth side 50 by a first distance d1, and they may be parallel to the fifth side 50. The second side 20 may be spaced apart from the sixth side 60 by a second distance d2, and may be parallel to the sixth side 60. The third side 30 may be spaced apart from the seventh side 70 by a third distance d3, and may be parallel to the seventh side 70. The fourth side 40 may be spaced apart from the eighth side 80 by a fourth distance d4, and may be parallel to the eighth side 80. Here, the first distance d1, the second distance d2, the third distance d3 and the fourth distance d4 may have the same length.

When patterning the planarization layer PL to form the second contact hole H2, the etched sidewall may have an inclined surface, so the separation length between the first contact hole H1 and the second contact hole H2 may be a marginal space for ensuring the inclined surface. One etched sidewall may be disposed on each of the fifth side 50, the sixth side 60, the seventh side 70 and the eighth side 80 configuring the second contact hole H2. FIG. 6 illustrates only the first sidewall SW1 formed on the fifth side 50 and the second sidewall SW2 formed on the eighth side 80.

The first contact hole H1 may have a first width H1W. The second contact hole H2 may have a second width H2W. The first contact hole H1 may be disposed within the second contact hole H2 as being apart from the second contact hole H2 with a predetermined distance. In the aspect of cross sectional view as FIG. 6, the first contact hole H1 may be apart from the second contact hole H2 with the first distance d1 and the fourth distance d4. That is, the second width H2W may be same with the summation of the first width H1W, the first distance d1 and the fourth distance d4.

Further, the pixel contact hole PH may be disposed at a predetermined distance from the color filter CF. When depositing and patterning the color filter CF, the color filter CF may be removed at the position where the pixel contact hole PH is to be formed, so that the pixel contact hole PH does not pass through the color filter CF. In particular, the color filter CF may be spaced apart from the second contact hole H2 by a contact margin width HMW, which is a predetermined distance from the second contact hole H2. For example, color filter CF may be disposed as being spaced apart by the margin width BMW from each of the fifth side 50, the sixth side 60, the seventh side 70 and the eighth side 80, respectively.

As the resolution of the display increases, the size of the pixel area PA decreases. Further, the emission area OA is also reduced. Accordingly, the size of the pixel contact hole PH may be reduced. Otherwise, the area ratio of the pixel contact hole PH increases, so the area of the pixel contact hole PH is an important factor that reduces the ratio of the emission area, i.e., the aperture ratio. In order to prevent a decrease in the aperture ratio, the size of the pixel contact hole PH should be reduced. However, the size of the pixel contact hole PH may not be reduced according to the reduction ratio of the pixel area PA. The reason is that a problem may occur in the connectivity between the anode electrode ANO and the driving drain electrode DD, when the size of the pixel contact hole PH is too small. Therefore, the pixel contact hole PH may not be reduced to a predetermined minimum size or less. As the result, even in a situation in which the size of the pixel area PA decreases as the resolution increases, the ratio of the size of the pixel contact hole PH to the size of the pixel area PA may rather increase.

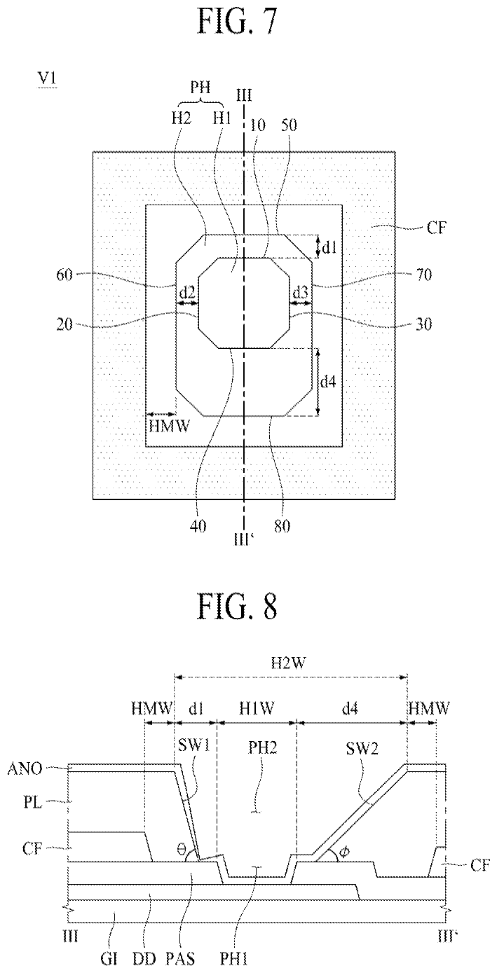

Considering the separation distance (or length) from the color filter CF, in order to maintain the area ratio occupied by the pixel contact hole PH, the inclination degrees of the etched sidewalls SW1 and SW2 may be increased in the process of forming the second contact hole H2. However, when the inclination degrees of the etched sidewall increases, the anode electrode ANO may become very thin or even breakage may occur at the bottom end of the second contact hole H2, as shown in FIG. 7. For example, the inclination angle θ of the first sidewall SW1 and the second sidewall SW2 of the second contact hole H2 may be less than 60 degrees. When the inclination angles θ of the first sidewall SW1 and the second sidewall SW2 exceed 60 degrees, the anode electrode ANO may be disconnected or become very thin to increase the electric resistance. As a result, the anode electrode ANO may become inoperable.

<Second Aspect>

Hereinafter, in the second aspect referring to FIGS. 7 and 8, FIG. 7 is an enlarged plane view illustrating a detailed structure of dotted circle part ‘V1’ in FIG. 3 according to the second aspect of the present disclosure. FIG. 8 is a cross-sectional view along to cutting line in FIG. 6, for illustrating a structure of an electroluminescence display according to the second aspect of the present disclosure.

The pixel contact hole PH may include a first contact hole H1 penetrating the passivation layer PAS and a second contact hole H2 penetrating the planarization layer PL. In a plane view, the first contact hole H1 and the second contact hole H2 may have a polygonal shape having four sides at least.

Since the second contact hole H2 is formed later than the first contact hole H1, the second contact hole H2 may have larger size than the first contact hole H1. In the second aspect, the first contact hole H1 may be arranged to be biased toward one side inside the second contact hole H2. In a plane view, the first contact hole H1 may be disposed to be included in the second contact hole H2. The first contact hole H1 may include a first side 10, a second side 20, a third side 30 and a fourth side 40. Similarly, the second contact hole H2 may include a fifth side 50, a sixth side 60, a seventh side 70 and a eighth side 80.

The separated distance between the first contact hole H1 and the second contact hole H2 may be set in consideration of a process margin. For example, the first side 10 spaced apart from the fifth side 50 by a first distance d1 and may be parallel to each other. The second side 20 may be spaced apart from sixth side 60 by a second distance d2 and may be parallel to each other. The third side 30 may be spaced apart from seventh side 70 by a third distance d3 and may be parallel to each other. The fourth side 40 may be spaced apart from eighth side 80 by a fourth distance d4 and may be parallel to each other. Here, the first distance d1, the second distance d2 and the third distance d3 may be the same each other. However, the fourth distance d4 may be longer than the first distance d1. As a result, the first contact hole H1 may have an arrangement structure in which it is biased closer to the fifth side 50 inside the second contact hole H2. From another aspect, only the eighth side 80 of the second contact hole H2 may be disposed to be spaced apart from the fourth side 40 with a longer distance than the other sides.

The first contact hole H1 is not limited to being biased closer to only the fifth side 50 inside the second contact hole H2. The first contact hole H1 may be biased toward either one of the fifth side 50 to the eighth side 80. That is, any one of the first distance d1 to the fourth distance d4 may be longer than the other three distances.

The first contact hole H1 may have a first width H1W. The second contact hole H2 may have a second width H2W. The first contact hole H1 may be disposed within the second contact hole H2 as being apart from the second contact hole H2 with a predetermined distance. In the aspect of cross sectional view as FIG. 8, the first contact hole H1 may be apart from the second contact hole H2 with the first distance d1 and the fourth distance d4. That is, the second width H2W may be same with the summation of the first width H1W, the first distance d1 and the fourth distance d4.

When the planarization layer PL is patterned to form the second contact hole H2, the etched sidewall may have an inclination surface. Therefore, the separation distance between the first contact hole H1 and the second contact hole H2 may be a marginal space for ensuring the inclined surface of the sidewall. Each one etched sidewall may be disposed at each of the fifth side 50, the sixth side 60, the seventh side 70 and the eighth side 80 configuring the second contact hole H2. In FIG. 9, the first sidewall SW1 formed on the fifth side 50 and the second sidewall SW2 formed on the eighth side 80 are illustrated.

Further, the pixel contact hole PH may be disposed with a predetermined distance from the color filter CF. When stacking and then patterning the color filter CF, by removing the color filter CF at the position where the pixel contact hole PH is formed, the pixel contact hole PH may be formed so as not to pass through the color filter CF. In particular, the color filter CF may be spaced apart from the second contact hole H2 by the contact hole marginal width HMW, which is a predetermined distance from the second contact hole H2. For example, the color filter CF may be disposed as being apart at the same distance, the contact hole marginal width HMW, from each of the fifth side 50, the sixth side 60, the seventh side 70 and the eighth side 80 forming the second contact hole H2. For example, the color filter CF may be disposed to be spaced apart from each of the fifth side 50, the sixth side 60, the seventh side 70 and the eighth side 80 configuring the second contact hole H2, by the contact hole marginal width BMW which is the same distance.

As described in the first aspect, in the process of forming the second contact hole H2 for high-ultra-resolution display, the inclination of the etched sidewall may have high inclinations. For example, the first sidewall may have a first inclination angle. Here, the first inclination angle θ may be larger than 50 degree. For example, the first inclination angle θ may be one between 60 degree and 80 degree. In the second aspect, the first inclination angle θ may be same with the inclination angle θ of the first aspect. In the second aspect, the first inclination angle θ may be larger than the inclination angle θ of the first aspect. Therefore, for the second aspect, the distance between the pixel contact hole PH and the color filter CF may be minimized in the direction of the first sidewall SW1.

However, when the inclination of the etched sidewall increases, the connectivity with the anode electrode ANO may be deteriorated. Accordingly, the second side wall SW2 may have the second inclination angle φ smaller than the first inclination angle θ. For example, the second inclination angle φ may be any one degree of 30 degree to 50 degree. As the result, the anode electrode ANO may be deposited on the planarization layer PL having a gentle slope at the eighth side 80 of the second contact hole H2, so the disconnection or thinning of the anode electrode ANO may not be occurred.

However, it is not limited to that the second sidewall SW2 has the second inclination angle φ smaller than the first inclination angle θ. In FIG. 7, the second sidewall SW2 may be a sidewall corresponding to the eighth side 80 which is a sidewall formed on a side furthest from the four sides configuring the second contact hole H2 among the four side configuring the first contact hole H1. Therefore, the second sidewall SW2 may be any one of the first side 10 to the fourth side 40. In another aspect, the sidewall on which any one of the first distance d1 to the fourth distance d4 having a separation distance longer than the other three distances may have a second inclination angle φ smaller than the first inclination angle θ, and the remaining three sidewalls may have the first inclination angle θ.

According to the second aspect of the present disclosure, when the resolution is increased, even though the ratio of the area of the pixel contact hole PH to the emission area OA increases, there is no defect or problem in the connectivity between the driving drain electrode DD and the anode electrode ANO through the pixel contact hole PH. In order to prevent a defect in connectivity of the anode electrode ANO, when the etched sidewalls of four sides configuring the second contact hole H2 have an etched sidewall of 30 degree to 50 degree, it is difficult to ensure the area ratio of the pixel contact hole PH to the minimum ratio.

The features, structures, effects and so on described in the above examples of the present disclosure are included in at least one example of the present disclosure, and are not limited to only one example. Furthermore, the features, structures, effects and the likes explained in at least one example may be implemented in combination or modification with respect to other examples by those skilled in the art to which this disclosure belongs. Accordingly, contents related to such combinations and variations should be construed as being included in the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the appended claims and their equivalents. These and other changes can be made to the aspects in light of the above-detailed description. In general, in the following claims, the terms used should not be construed to limit the claims to the specific aspects disclosed in the specification and the claims, but should be construed to include all possible aspects along with the full scope of equivalents to which such claims are entitled. Accordingly, the claims are not limited by the disclosure.

What is claimed is:

1. An electroluminescence display comprising:
a pixel area disposed on a substrate and including an emission area and a non-emission area;
a driving element disposed in the non-emission area;
a passivation layer on the driving element;
a color filter disposed in the pixel area on the passivation layer;
a planarization layer on the color filter;
a first contact hole penetrating through the passivation layer and exposing the driving element;
a second contact hole penetrating through the planarization layer and exposing the first contact hole; and
a light emitting element disposed at the emission area on the planarization layer and connecting to the driving element through the second contact hole and the first contact hole,
wherein the first contact hole is disposed in the second contact hole as being biased toward a first side.

2. The electroluminescence display according to claim 1, wherein the color filter is spaced apart from the second contact hole with a predetermined distance.

3. The electroluminescence display according to claim 1, wherein the second contact hole includes:
a first side having a first inclined angle; and
a second side having a second inclined angle smaller than the first inclined angle,
wherein the first side is disposed at the first side of the second contact hole, the first side is closest apart from the first contact hole, and
wherein the second side is disposed at a second side of the second contact hole, the second side is furthest apart from the first contact hole.

4. The electroluminescence display according to claim 3, wherein the first inclined angle is between 60 degree and 80 degree, and the second inclined angle is between 30 degree and 50 degree.

5. The electroluminescence display according to claim 1, wherein the first contact hole includes a first side, a second side, a third side and a fourth side,
wherein the second contact hole includes a fifth side parallel to and is spaced apart from the first side with a first distance, a sixth side parallel to and spaced apart from the second side with a second distance, a seventh side parallel to and spaced apart from the third side with a third distance, and a eighth side parallel to and spaced apart from the fourth side with a fourth distance,
wherein the first distance and the second distance and the third distance are same, and
wherein the fourth distance is longer than the first distance.

6. The electroluminescence display according to claim 5, wherein the second contact hole includes:
a first inclined sidewall disposed at the fifth side; and
a second inclined sidewall disposed at the eighth side, and
wherein the second inclined sidewall has a second inclined angle smaller than a first inclined angle of the first inclined sidewall.

7. The electroluminescence display according to claim 6, wherein the first inclined angle is between 60 degree and 80 degree, and the second inclined angle is between 30 degree and 50 degree.

8. The electroluminescence display according to claim 1, wherein the light emitting element includes:
a first electrode connected to the driving element;
an emission layer disposed on the first electrode; and
a second electrode disposed on the emission layer.

9. The electroluminescence display according to claim 8, wherein the first electrode includes a transparent conductive material having one of indium-zinc-oxide and indium-tin-oxide.

10. The electroluminescence display according to claim 8, wherein the second electrode includes a reflective metal material having one of aluminum, silver, molybdenum, gold, magnesium, calcium and barium.

11. The electroluminescence display according to claim 1, wherein the driving element includes:
a semiconductor layer on the substrate;
a gate insulating layer on the semiconductor layer;
a gate electrode on the gate insulating layer, the gate electrode overlapping with a middle portion of the semiconductor layer;
a source electrode on the gate insulating layer, the source electrode contacting one side of the semiconductor layer; and
a drain electrode on the gate insulating layer, the drain electrode contacting another side of the semiconductor layer.
